(19) United States
(12) Patent Application Publication
(10) Pub. No.: US 2011/0193043 A1
(43) Pub. Date: Aug. 11, 2011

(54) Ultra-Low Energy RRAM with Good Endurance and Retention

(76) Inventor: Albert Chin, Taipei City (TW)

(21) Appl. No.: 12/700,726

(22) Filed: Feb. 5, 2010

(51) Int. Cl. H01L 45/00

(52) U.S. Cl. 257/2; 257/E45.001; 257/43

(57) ABSTRACT

This invention proposes an ultra-low energy (ULE) RRAM with electrode_{—}1/covalent-bond-dielectric/metal-oxide/electrode_{—}2/substrate structure, where the sequence of covalent-bond-dielectric layer and metal-oxide layer is exchangeable. Stacked dielectric layers of covalent-bond-dielectric and metal-oxide are used to improve the switching power and energy, retention and cycling endurance of resistance random access memory.

### BACKGROUND OF THE INVENTION

1. Technical Field

The invention relates to a Novel Ultra-Low-Energy (ULE) Resistance Random Access Memory (RRAM) device. More particularly, the invention relates to an ultra-low energy RRAM of electrode_1/dielectric_1/dielectric_2/electrode_2 device on a substrate, which has larger memory window, long stored data retention and good SET-RESET cycling endurance.

2. Description of Related Art

The RRAM of Hyunjun Sim, Hyejung Choi, Dongsoo Lee, Man Chang, Dooho Choi, Yunik Son, Eun-Hong Lee, Wonjoo Kim, Yoondong Park, In-Kyeong Yoo and Hyunsang Hwang, “Excellent Resistance Switching Characteristics of Pt/SrTiO₃ Schottky Junction for Multi-bit Nonvolatile Memory Application,” in IEDM Tech. Dig., 2005, pp. 777-780 hereafter refer as [1] and U. Russo, D. Ielmini, C. Cagli, A. L. Lacaita, S. Spiga, C. Wiemer, M. Perego and M. Fanciulli, “Conductive-filament switching analysis and self-accelerated thermal dissolution model for reset in NiO-based RRAM,” in IEDM Tech. Dig., 2007, pp. 775-778 hereinafter refer as [2] provide a potential solution for highly scaled non-volatile memory (NVM). FIG. 1 shows the typical energy band diagram of the conventional RRAM NVM using metal-oxide as the dielectric layer. There are two types of RRAM: the bipolar [1] and unipolar [2] operation modes that are summarized in Table 1. For prior-art of bipolar RRAM using Nb-doped SrTiO_{3 (STO) [}1], a forming voltage is first applied between metal electrode 10 and metal electrode 12 that causes a high current flow and form a low resistance state (LRS). The high resistance state (HRS) can be RESET back by applying an opposite polarity voltage and current (e.g.: −3 V and −10 mA in Table 1 [1]). Then the LRS can be SET back by applying an opposite polarity voltage and current (e.g.: 1 V and 10 mA in Table 1 [1]). The cycles between LRS and HRS can continue by applying opposite polarity SET and RESET voltage and current. As shown in Table 1, good NVM characteristics of long retention and cycling endurance are obtained in this bipolar RRAM. However, a transistor is needed to drive the opposite polarity current and voltage in the bipolar RRAM, during SET and RESET, which forms the 1-resistor-1-transistor (1R1T) structure. Unfortunately the cell size of 1R1T is larger than the diode-driven unipolar RRAM of 1-resistor-1-diode (1R1D) structure or simple 1R structure. Besides, the high SET and RESET currents require a large size transistor to drive.

The above issues could be partially addressed by the unipolar RRAM. For prior-art unipolar RRAM using NiO metal-oxide [2], a forming voltage is first applied to dielectric 11 that leads to LRS with a high current flow. To prevent the irreversible and permanent dielectric breakdown, a current compliance is applied to limit the maximum allowed current. The HRS can be RESET back by applying the same polarity voltage and current (e.g.: 1.4 V and 5 mA in Table 1 [2]). The LRS can be SET back by applying the same polarity voltage and current (e.g.: 3.9 V and 0.6 mA in Table 1 [2]). However, the high compliance current needs a large size transistor that is opposite to the requirement of high-density low-energy memory. This RESET condition is particularly critical, since it requires relatively high energy (high current and long times) to return to HRS. Besides, the poor endurance, high forming energy and needed large transistor for current compliance are the challenges for unipolar RRAM [2]. The vital issues for both bipolar and unipolar RRAM are the very high SET and RESET current and energy, the using high-cost noble-metal electrode and small HRS/LRS memory window that are the fundamental limitation for high-density and low-energy NVM.

### BRIEF SUMMARY OF THE INVENTION

To overcome the drawbacks of the prior arts, this invention proposes a novel ULE RRAM on a substrate. The energy band diagram is shown in FIG. 2, which has a bottom metal electrode 20, stacked dielectric_2 21, dielectric_1 22 and a top metal electrode 23. During SET, a voltage is applied between electrode 23 and 20. The uniqueness of this invention is the high SET resistance to cause self-compliance that does not require external current compliance using a transistor. In addition, very small RESET current and voltage to HRS is reached in this device, which can be provided by a diode at reverse-biased condition. Besides, large on/off ratio >10⁵, big extrapolated 10-year retention memory window >10⁵ at 85° C., excellent endurance up to 10⁶ cycles and fast 50 ns switching time are also obtained simultaneously in this RRAM device. Such record high performances were achieved using the covalent-bond-dielectric/metal-oxide stack, but unreachable for all metal-oxides stack. This is further supported by the measured negative temperature coefficient (TC) in this device that is quite different from the positive TC in conventional metal-oxide unipolar RRAM [2]. Therefore, the good NVM device integrity is due to the different conduction mechanism compared with conventional metal-oxide RRAM.

To implement this device, this have used the TaN bottom electrode, bottom dielectric_2 of metal-oxide STO, top dielectric_1 of covalent-bond-dielectric GeO₂ (GeO) and top electrode Ni as an example. Other combination of covalent-bond-dielectric such as binary oxide and nitride of SiO₂, Si₃N₄, Ge₃N₄, AlN, GaN, InN etc and the combination of these dielectrics of SiON, GeON, AlGaN, AlGaON etc can also be implemented in this RRAM device. The fabricated ULE device showed record high RRAM performance of ultra-low 4 W SET power (−3.5 A at −1.1 V), extremely-low 16 pW RESET power (0.12 nA at 0.13 V), very large extrapolated 10-year on/off retention window of 4×10⁵ at 85° C., good 10⁶ cycling endurance and fast 50 ns switching time for the first time. In comparing with data [1]-[2] in Table 1, our device has the lowest power and energy, the best 10-year extrapolated retention memory window of HRS/LRS and the good cycling endurance at the same time.

TABLE 1
Comparison of device integrity data for various
RRAM devices.

| | | | | | | | | | Power | | Energy | |
|---|---|---|---|---|---|---|---|---|---|---|---|---|
| | Up/Lower | I_{SET} | | I_{RESET} | | HRS/LRS | | Cycle, | SET, | | SET, | |
| Dielectric | Electrode | V_{SET} | | V_{RESET} | | Ratio | Retention | pulse | RESET | | RESET | |
| Nb:STO | Pt/Pt | 10 | mA | −10 | mA | ~10² | 2 × 10⁶, | 2 × 10⁷, | 10 | mW, | 5 | uJ, |
| [1] | | 1 | V | −3 | V | | 125 C. | 500 us | 30 | mW | 15 | uJ |
| bipolar | | | | | | | | | | | | |
| NiO [2] | Au/n-Si | 0.6 | mA | 5 | mA | ~2 × 10² | — | — | 2.3 | mW, | — | |
| unipolar | | 3.9 | V | 1.4 | V | | | | 7 | mW | — | |
| GeO/STO | Ni/TaN | −3.5 | uA | 0.12 | nA | >10⁵ | 10⁵, | 10⁶, | 4 | uW, | 375 | fJ* |
| This | | −1.1 | V | 0.13 | V | | 85 C. | 50 ns | 16 | pW | 0.003 | fJ* |
| invention | | −5 | uA* | ~0.12 | nA* | | | | | | | |
| | | −1.5 | V* | 0.5 | V* | | | | | | | |

*under overstress during cycling

### BRIEF DESCRIPTION OF THE DRAWINGS

FIG. 1. Schematic energy band diagram of a conventional electrode/dielectric/electrode RRAM device formed on a substrate.

FIG. 2. Schematic energy band diagram of the electrode_1/dielectric_1/dielectric_2/electrode_2 ULE RRAM device formed on a substrate, wherein stacked covalent-bond-dielectric and metal-oxide are used and the sequence can be reversed.

FIG. 3. Swept I-V curves of conventional Ni/STO/TaN RRAM formed on a SiO₂/Si substrate wherein the arrows indicate the bias sweeping direction.

FIG. 4. Swept I-V curves of covalent-bond-dielectric Ni/GeO/TaN RRAM formed on a SiO₂/Si substrate with different thickness of GeO.

FIG. 5. Swept I-V curves of forming-free stacked Ni/GeO/STO/TaN RRAM formed on a SiO₂/Si substrate, with STO deposited at normal and oxygen-deficient conditions.

FIG. 6. Swept I-V curves of stacked all metal-oxides Ni/HfO₂/STO/TaN RRAM formed on a SiO₂/Si substrate. Very poor HRS/LRS is measured at 0.2 V.

FIG. 7. Swept I-V curves dependent on GeO thickness. Pure unipolar transition (0 V reset) is reached in thinner GeO.

FIG. 8. Swept I-V curves of Ni/GeO/STO/TaN RRAM formed on a SiO₂/Si substrate wherein both new-type unipolar-like and conventional unipolar modes are obtained.

FIG. 9. V_{SET} and V_{RESET} distributions of the new unipolar-like RRAM devices.

FIG. 10. I-V characteristics of (a) HRS and (b) LRS by fitting with Schottky emission and ohmic conduction mechanisms, respectively.

FIG. 11. Temperature dependent HRS and LRS of Ni/GeO/STO/TaN RRAM and showing negative temperature coefficient.

FIG. 12. LRS resistance as a function of temperature. The insert figure shows the energy band diagram and hopping conduction in GeO/STO.

FIG. 13. Endurance of Ni/GeO/STO/TaN RRAM formed on a SiO₂/Si substrate wherein the 50 ns is limited by equipments of pulse generator and oscilloscope and stable switching is obtained up to 10⁶ cycles.

FIG. 14. Retention of Ni/GeO/STO/TaN RRAM formed on a SiO₂/Si substrate wherein extrapolated 10-year retention window of 4×10⁵ is reached at 85° C.

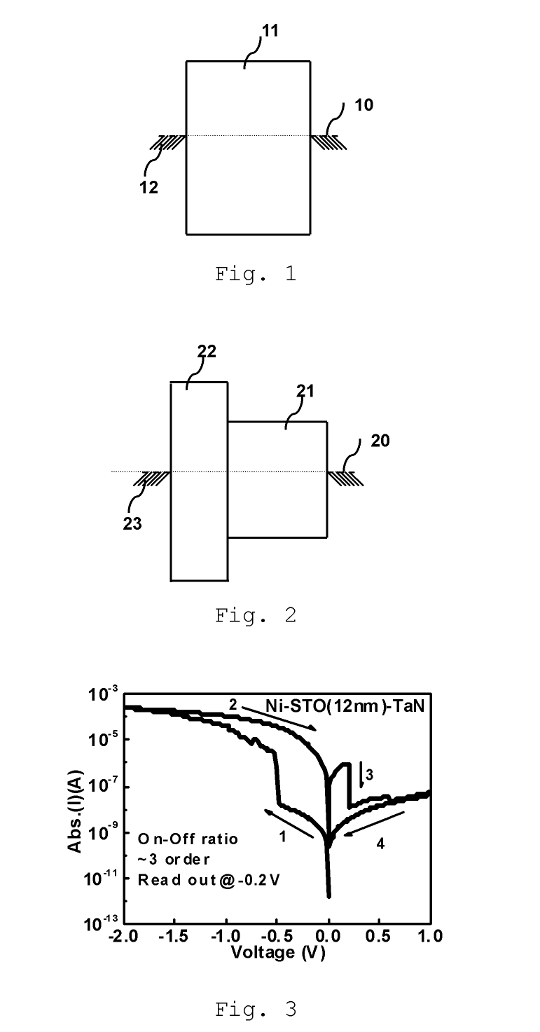

### DETAILED DESCRIPTION OF THE INVENTION

For the best understanding of this invention, please refer to the following detailed description of the preferred embodiments and the accompanying drawings, wherein:

In view of the drawbacks of the prior arts, this invention proposes an ULE RRAM for better scalability, lower power and energy, larger memory window, good retention, fast SET/RESET switching and low temperature process. The using stacked covalent-bond-dielectric/metal-oxide 22-21 of GeO/STO permits much lower SET and RESET currents than conventional RRAM [1]-[2]. The using low cost electrodes with different work-function of Ni (5.1 eV) and TaN (4.6 eV) are also useful to reach the ULE RRAM.

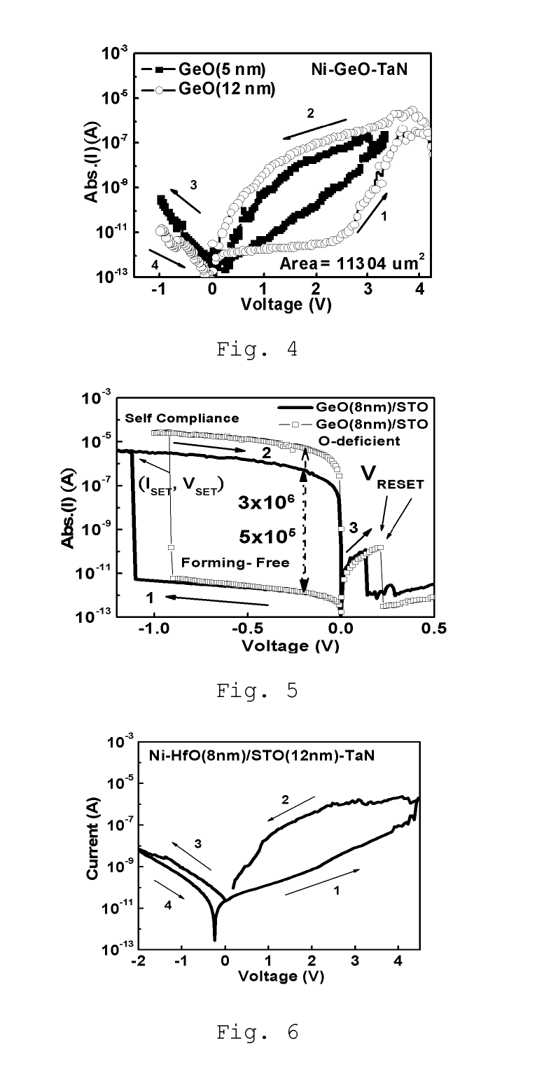

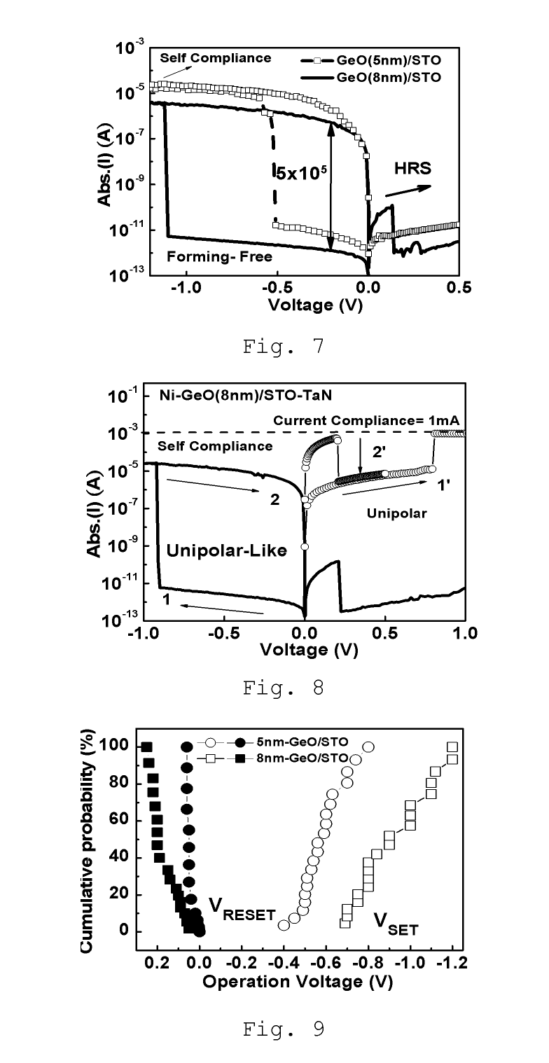

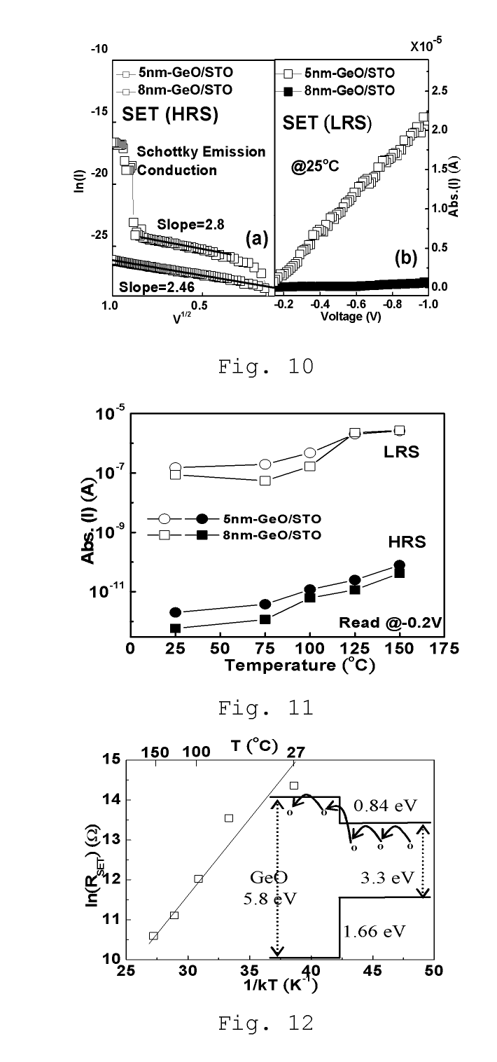

FIG. 3 shows the swept I-V curves of control Ni/STO/TaN RRAM. The very high 0.3 mA SET current at −2 V is the basic limitation for conventional RRAM. The bipolar mode operation, with opposite polarity current and voltage during SET and RESET, needs a large size transistor for 1R1T operation rather than a small area diode for 1R1D operation. FIG. 4 shows the swept I-V curves of covalent-bond Ni/GeO/TaN RRAM. In sharp contrast to the metal-oxide RRAM in FIG. 3, a small SET current of 3-0.2 A and very low RESET current of 5˜150 pA are measured. The unique behavior in Ni/GeO/TaN may be related to electron injection created defects in GeO from lower work-function TaN (4.6 eV) than top Ni (5.1 eV), since no metallic filaments can be formed in covalent-bond-dielectric. To further use the merits of low RESET voltage STO and low SET current GeO, this invention formed the Ni/GeO/STO/TaN device on a SiO₂/Si substrate processed at room temperature (FIG. 5). Very low self-compliance SET current of −3.5 A at −1.1 V (4 W), RESET current of 0.12 nA at 0.13 V (16 pW) and very large HRS/LRS memory window of 5×10⁵ are reached that are among the best reported data to date [1]-[2]. The very small reset current and voltage can be driven by a diode at reverse bias and behavior as a unipolar-like operation. Even larger 3×10⁶ HRS/LRS is obtained for the same structured device when the STO was deposited at oxygen-deficient condition. It is important to notice that the Ni/GeO/STO/TaN device is processed at room temperature. Therefore, this device can be fabricated on other low-temperature materials such as glass, metal, plastic, paper, cloth etc. In sharp contrast, much poor HRS/LRS and high RESET voltage and current are measured in stacked all metal-oxides Ni/HfO₂/STO/TaN RRAM shown in FIG. 6, indicating the importance of using covalent-bond-dielectric. The SET voltage and current depend strongly on GeO thickness shown in FIG. 7. The decreasing GeO thickness decreases the SET voltage, where even 0 V reset, the pure unipolar mode, is obtained at thinner GeO. Such diode driven unipolar-like RRAM is preferred for simple array operation and vertical three-dimensional (3D) stacking. This unipolar-like RRAM is different to conventional unipolar mode that is also obtainable in the same device under positive voltage and current compliance condition shown in FIG. 8, but this operation suffered from high set current, poor endurance [2], high current compliance related large size transistor, and high forming power allied unpredictable resistance states. This device has good SET and RESET voltage distribution shown in FIG. 9. Since the HRS/LRS is as high as 5×10⁵, simple operation of cross-point array can be realized to first RESET all cells to HRS. Then the selected cells are written to LRS. The stored resistance states are read out by applying a small V_{read} to cells (0.2 V in this study).

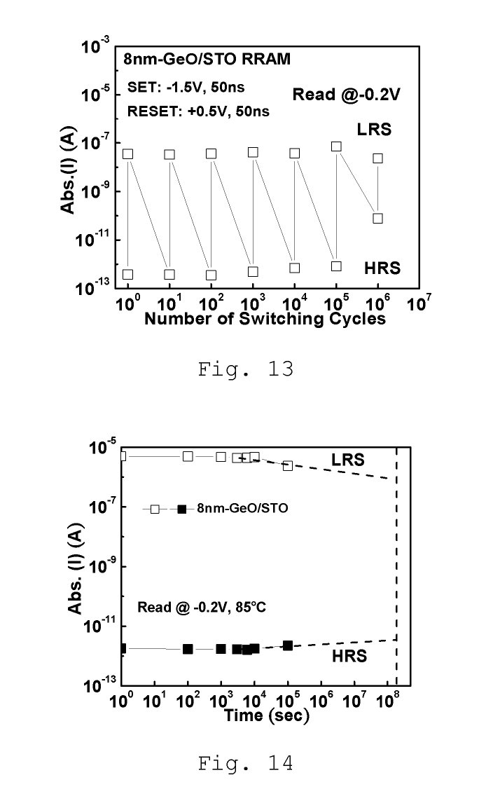

To further understand the record lowest current and power, this invention measured the temperature-dependent currents shown in FIG. 10. The very small HRS current is due to the Schottky emission via high work-function Ni electrode. The current at LRS follows the ohmic law, and the slight current variation is related to carrier trapping/de-trapping. FIG. 11 is the temperature dependence and the resistance at LRS vs. temperature is plotted in FIG. 12. A negative TC is measured up to 150° C. that is opposite to the positive TC in conventional metal-oxide RRAM [2]. The activation energy of 0.35 eV is close to that of the same negative TC in highly defective Si ruled by hopping conduction. This suggests LRS mechanism to be related by hopping via defects. The main defects may be oxygen vacancies due to the improved HRS/LRS memory window at oxygen-deficient STO shown in FIG. 5. Such weakly linked hopping conduction via oxygen vacancies can be easily disconnected by injected electrons over low work-function TaN at a small positive voltage, which is quite different from the needed high voltage and current for metallic filament conduction in metal-oxide RRAM [2]. This also explains the measured very low RESET power in FIG. 5.

FIG. 13 shows the endurance characteristics. Excellent endurance up to 10⁶ at fast 50 ns cycling is reached under over stressed SET and RESET voltages, in addition to the ultra-low SET energy of 375 fJ (−5 A, −1.5 V & 50 ns) and record lowest RESET energy of 0.003 fJ (0.12 nA, 0.5 V & 50 ns). Such small switching energy is vital to save energy in green memory devices. FIG. 14 shows the retention characteristics. A large 10-year extrapolated memory window of 4×10⁵ at 85° C. is also reached. Table 1 compares and summarizes the memory data. This new device has 10⁴ times lower power and 10⁷ times lower energy than the reported RRAM [1]-[2] with good cycling endurance and retention at the same time.

Although a preferred embodiment of the invention has been described for purposes of illustration, it is understood that various changes and modifications to the described embodiment can be carried out without departing from the scope and the spirit of the invention as disclosed in the appended claims.

What is claimed is:

1. An Ultra-Low Energy (ULE) RRAM device for simple cross-point memory and three-dimensional array has the structure of electrode_1/covalent-bond-dielectric/metal-oxide/electrode_2 or exchanged sequence of electrode_1/metal-oxide/covalent-bond-dielectric/electrode_2 formed on a substrate, wherein stacked covalent-bond-dielectric layer and metal-oxide layer are used for ULE switching operation.

2. An ULE RRAM device according to claim 1, wherein the covalent-bond-dielectric layer can be binary oxide and nitride of SiO₂, GeO₂, Si₃N₄, Ge₃N₄, AlN, GaN, InN, and the combination of these dielectrics to form ternary and quaternary covalent-bond-dielectric.

3. An ULE RRAM device according to claim 1, wherein the metal-oxide layer can be the binary metal-oxide in the periodic table and the combination of these metal-oxides.

4. An ULE RRAM device according to claim 1, wherein the electrode can be metal, metal-nitride, impurity-doped poly-crystalline or amorphous semiconductor and organic semiconductors.

5. A ULE RRAM device according to claim 1, wherein the substrate can be semiconductor, glass, insulator, metal, organic, paper and cloth materials.
